(19) United States
(12) Patent Application Publication
(10) Pub. No.: US 2005/0020059 A1
(43) Pub. Date: Jan. 27, 2005

(54) Method for forming aluminum-containing interconnect

(76) Inventors: Yi-Nan Chen, Taipei (TW); Kuo-Chien Wu, Miaoli (TW)

Correspondence Address: BIRCH STEWART KOLASCH & BIRCH, PO BOX 747, FALLS CHURCH, VA, 22040-0747, US

(21) Appl. No.: 10/800,695

(22) Filed: Mar. 16, 2004

(30) Foreign Application Priority Data
Jul. 25, 2003 (TW) 92120356

(51) Int. Cl. H01L 21/4763

(52) U.S. Cl. 438/648

(57) ABSTRACT

A method for forming an aluminum-containing interconnect is provided. The method includes providing a substrate with a contact region. A first barrier layer, an aluminum-containing conductive layer, and a second barrier layer are sequentially formed over the substrate, and then patterned to form an aluminum-containing interconnect. The aluminum-containing interconnect is electrically coupled to the contact region and has a sidewall exposed. A barrier spacer is formed on the sidewall of the aluminum-containing interconnect by using a material selected from a group consisting of titanium, titanium nitride, and the combination thereof.

### CROSS REFERENCE TO RELATED APPLICATIONS

This application claims priority to Taiwan Patent Application No. 92120356 entitled “Method for Forming Aluminum Containing Interconnect”, filed on Jul. 25, 2003.

### FIELD OF INVENTION

The present invention generally relates to a method for forming an interconnect in a semiconductor device, and more particularly, to a method for forming an aluminum-containing interconnect in a semiconductor device.

### BACKGROUND OF THE INVENTION

As the density of integrated circuits increases, the interconnections (or metallization) between devices become more and more important. The multilevel metallization structure includes alternating layers of dielectric and metal materials. Most commonly, the metal layers mainly contains aluminum or aluminum alloy. Aluminum becomes one of the most important materials for metallization process because of its good conductivity, proper adhesion to other layers, and being easy to be etched.

However, because the aluminum has a relatively low melting point and is susceptible to high temperature, extrusions are likely to occur from the sidewall of the aluminum-containing interconnects. As geometries have shrunk, the spaces between interconnects have decreased. Problems induced by extrusions of aluminum-containing interconnects become more and more significant. For example, devices usually fail because of interconnection short due to extrusions of aluminum-containing interconnects.

Therefore, there is a need to provide a method for forming an aluminum-containing interconnect capable of suppressing extrusions.

### SUMMARY OF THE INVENTION

One aspect of the present invention is to provide a method for forming an aluminum-containing interconnect which has a barrier spacer preventing extrusions from the sidewall of an aluminum-containing conductive layer.

Another aspect of the present invention is to provide a method for forming an aluminum-containing interconnect, which has a barrier layer selected from a group consisting of titanium, titanium nitride and the combination thereof to encapsulate an aluminum-containing conductive layer and prevent interconnection short.

In one embodiment of the present invention, a method for forming an aluminum-containing interconnect structure includes providing a substrate having a contact region. A first barrier layer, an aluminum-containing conductive layer, and a second barrier layer are sequentially formed over the substrate. The second barrier layer, the aluminum-containing conductive layer, and the first barrier layer are patterned to form an aluminum-containing interconnect, which is coupled the contact region and exposes a sidewall of the aluminum-containing conductive layer. A barrier spacer is then formed on the sidewall of the aluminum-containing interconnect. The first barrier layer, the second barrier layer, and the barrier spacer are independently selected from a group consisting of titanium, titanium nitride, and the combination thereof. Moreover, the barrier spacer is a titanium rich titanium nitride spacer having an atom ratio of titanium to nitrogen larger than 1 (Ti/N>1).

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a cross-sectional view of forming a second barrier layer in one embodiment of the present invention;

FIG. 2 illustrates a cross-sectional view of forming a patterned photoresist layer in an exemplary embodiment of the present invention;

FIG. 3 illustrates a cross-sectional view of forming an aluminum-containing conductive layer in an exemplary embodiment of the present invention;

FIG. 4 illustrates a cross-sectional view of forming a conformal barrier layer in an exemplary embodiment of the present invention; and

FIG. 5 illustrates a cross-sectional view of forming a barrier spacer in an exemplary embodiment of the present invention.

### DETAILED DESCRIPTION OF THE INVENTION

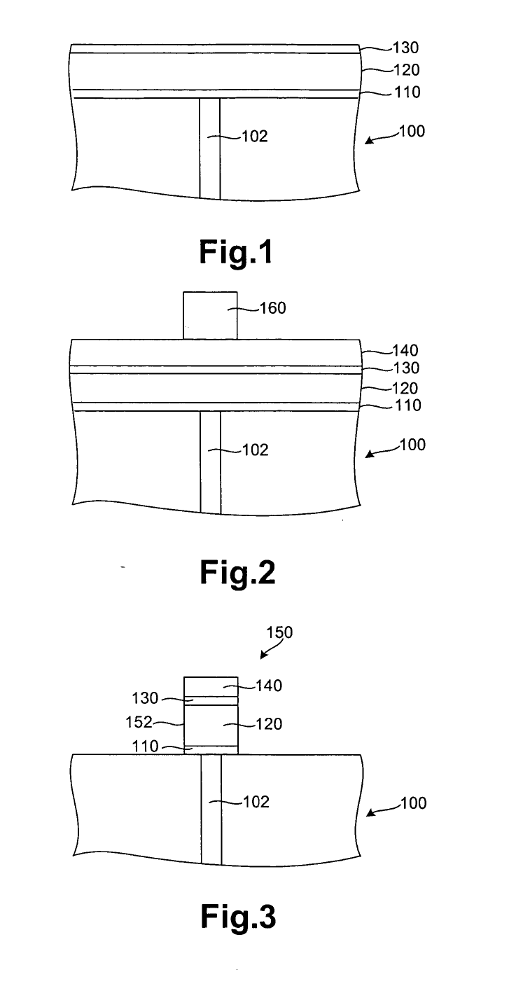

The present invention discloses a method for forming an aluminum-containing interconnect. Referring to FIG. 1, in one embodiment, the method includes providing a substrate 100. The substrate 100 has a contact region 102. The substrate 100 can be a substrate at any stage of forming a semiconductor device which needs interconnection; for example, a memory device in the metallization stage. The contact region 102 can be any region requiring subsequent electrical connections, for example, a via contact region. A first barrier layer 110 is then formed on the substrate 100. The first barrier layer 110 is formed, for example but not limited to, by using a material selected from a group consisting of titanium, titanium nitride, and the combination thereof. Then, an aluminum-containing conductive layer 120 is formed on the first barrier layer 110. The aluminum-containing conductive layer 120 can be an aluminum layer, an aluminum alloy layer, and the combination thereof. The aluminum alloy can be, for example, aluminum copper alloy. A second barrier layer 130 is formed on the aluminum-containing conductive layer 120. The second barrier layer 130 is formed, for example but not limited to, by using a material selected from a group consisting of titanium, titanium nitride, and the combination thereof.

As shown in FIG. 2, a hard mask layer 140 is optionally formed on the second barrier layer 130. The hard mask layer 140 enhances the protection for the underlying layers against the etching process. Then, the second barrier layer 130, the aluminum-containing conductive layer 120, and the first barrier layer 110 are patterned to form an aluminum-containing interconnect 150 (the hard mask 140 is also patterned if it is implemented). As shown in FIG. 3, the aluminum-containing interconnect 150 couples the contact region 102 and exposes a sidewall 152. Referring to FIG. 2, the step of forming the aluminum-containing interconnect 150 includes forming a patterned photoresist layer 160 on the hard mask layer 140. If no hard mask layer, the patterned photoresist layer 160 is directly formed on the second barrier layer 130. The patterned photoresist layer 160 defines the aluminum-containing interconnect 150 and cane be formed by conventional photoligraphy processes. Then, the hard mask layer 140, the second barrier layer 130, the aluminum-containing conductive layer 120, and the first barrier layer 110 are etched to form the aluminum-containing interconnect 150 by using the patterned photoresist layer 160 as a mask. As shown in FIG. 3, the patterned photoresist layer 160 is then removed.

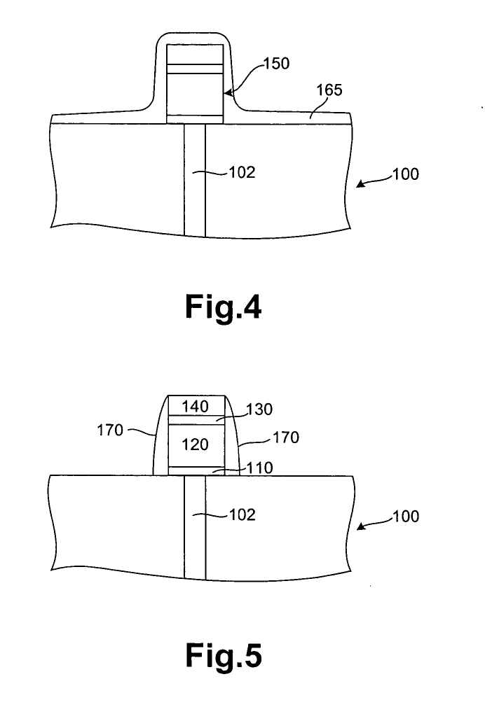

A barrier spacer 170 is formed on the sidewall 152 of the aluminum-containing interconnect 150 so as to prevent extrusions of the aluminum-containing conductive layer 120 and connection short of the interconnects. As shown in FIG. 4, the step of forming the barrier spacer 170 includes forming a conformal barrier layer 165 on the aluminum-containing interconnect 150 and the substrate 100. The conformal barrier layer 165 can be a layer selected from a group consisting of titanium layer, titanium nitride layer, and the combination thereof. In other words, the conformal barrier layer 165 is formed over the substrate 100 with the profile of the aluminum-containing interconnect 150 by using a material selected from a group consisting of titanium layer, titanium nitride layer, and the combination thereof. For example, the conformal barrier layer 165 is a titanium/titanium nitride or titanium nitride/titanium layer having a thickness about 300 Å. When the titanium layer has a thickness in a range from 0 to 300 Å, the titanium nitride layer has a thickness in a range from 300 to 0 Å. Furthermore, the conformal barrier layer can be a titanium rich titanium nitride layer having an atom ratio of titanium to nitrogen larger than 1 (Ti/N>1). Then, the conformal barrier layer 165 is anisotropically etched to form the barrier spacer 170, such as titanium spacer, titanium nitride spacer, or titanium/titanium nitride spacer. It is noted that by adjusting the thickness of the conformal barrier layer 165 the thickness or the width of the barrier spacer 170 can be controlled.

As shown in FIG. 5, the first barrier layer 110, the second barrier layer 130, and the barrier spacer 170 encapsulate the aluminum-containing conductive layer 120 so as to prevent extrusions of the aluminum-containing conductive layer 120 and connection short of interconnects and improve the device reliability. It is noted that though exemplary materials for the first barrier layer 110, the second barrier layer 130, and the barrier spacer 170 are titanium, titanium nitride, or titanium/titanium nitride, they can be independently selected to be the same or different material. Furthermore, the titanium, titanium nitride, or titanium/titanium nitride layer can be formed by conventional sputtering or deposition processes, or the titanium layer can be converted to the titanium nitride layer by nitridation processes. The method further includes a step of filling the space between the aluminum-containing interconnects 150 with dielectric materials and other steps for complete formation of a device.

Although specific embodiments have been illustrated and described, it will be obvious to those skilled in the art that various modifications may be made without departing from what is intended to be limited solely by the appended claims.

1. A method for forming an aluminum-containing interconnect structure, comprising:
providing a substrate having a contact region;
forming a first barrier layer on said substrate;
forming an aluminum-containing conductive layer on said first barrier layer;
forming a second barrier layer on said aluminum-containing conductive layer;
patterning said second barrier layer, said aluminum-containing conductive layer, and said first barrier layer to form an aluminum-containing interconnect, said aluminum-containing interconnect coupling said contact region and exposing a sidewall; and
forming a barrier spacer on said sidewall of said aluminum-containing interconnect.

2. The method of claim 1, wherein said contact region comprises a via contact region.

3. The method of claim 1, wherein said aluminum-containing conductive layer is selected from a group consisting of an aluminum layer, an aluminum alloy layer, and the combination thereof.

4. The method of claim 1, wherein said step of forming said first barrier layer comprises using a material selected from a group consisting of titanium, titanium nitride, and the combination thereof to form said first barrier layer.

5. The method of claim 1, wherein said step of forming said second barrier layer comprises using a material selected from a group consisting of titanium, titanium nitride, and the combination thereof to form said second barrier layer.

6. The method of claim 1, wherein said step of forming said aluminum-containing interconnect comprises:
forming a patterned photoresist layer on said second barrier layer, said patterned photoresist layer defining said aluminum-containing interconnect;
etching said second barrier layer, said aluminum-containing conductive layer, and said first barrier layer by using said patterned photoresist layer as a mask; and
removing said patterned photoresist layer.

7. The method of claim 1, wherein said step of forming said barrier layer comprises:
forming a conformal barrier layer selected from a group consisting of titanium, titanium nitride, and the combination thereof on said aluminum-containing interconnect and said substrate; and
anisotropically etching said conformal barrier layer.

8. The method of claim 7, wherein said step of forming said conformal barrier layer comprises forming a titanium/titanium nitride or titanium nitride/titanium layer having a thickness about 300 Å, and when said titanium layer has a thickness in a range from 0 to 300 Å, said titanium nitride layer has a thickness in a range from 300 to 0 Å.

9. The method of claim 1, wherein said step of forming said conformal barrier layer comprises forming a titanium rich titanium nitride layer having an atom ratio of titanium to nitrogen larger than 1 (Ti/N>1).

10. A method for forming an aluminum-containing interconnect structure, comprising:
providing a substrate having a contact region;
forming a first barrier layer on said substrate;
forming an aluminum-containing conductive layer on said first barrier layer;
forming a second barrier layer on said aluminum-containing conductive layer;
patterning said second barrier layer, said aluminum-containing conductive layer, and said first barrier layer to form an aluminum-containing interconnect, said aluminum-containing interconnect coupling said contact region and exposing a sidewall; and
forming a barrier spacer selected from a group consisting of titanium, titanium nitride, and the combination thereof on said sidewall of said aluminum-containing interconnect.

11. The method of claim 10, wherein said aluminum-containing conductive layer is selected from a group consisting of an aluminum layer, an aluminum alloy layer, and the combination thereof.

12. The method of claim 10, wherein said step of forming said first barrier layer comprises using a material selected from a group consisting of titanium, titanium nitride, and the combination thereof to form said first barrier layer.

13. The method of claim 10, wherein said step of forming said second barrier layer comprises using a material selected from a group consisting of titanium, titanium nitride, and the combination thereof to form said second barrier layer.

14. The method of claim 10, wherein said step of forming said aluminum-containing interconnect comprises:
forming a patterned photoresist layer on said second barrier layer, said patterned photoresist layer defining said aluminum-containing interconnect;
etching said second barrier layer, said aluminum-containing conductive layer, and said first barrier layer by using said patterned photoresist layer as a mask; and
removing said patterned photoresist layer.

15. The method of claim 10, wherein said step of forming said barrier layer comprises:
forming a conformal titanium/titanium nitride layer having a thickness of about 300 Å on said aluminum-containing interconnect and said substrate, wherein when said titanium layer has a thickness in a range from 0 to 300 Å, said titanium nitride layer has a thickness in a range from 300 to 0 Å; and
anisotropically etching said conformal titanium/titanium nitride layer.

16. The method of claim 10, wherein said step of forming said barrier spacer comprises forming a titanium rich titanium nitride spacer having an atom ratio of titanium to nitrogen larger than 1 (Ti/N>1).
